(19) United States
(12) Patent Application Publication
(10) Pub. No.: US 2026/0163526 A1
(43) Pub. Date: Jun. 11, 2026

(54) DRIFT RESET CIRCUIT FOR UPDATING THE INPUT OFFSET VOLTAGE IN AN IONIZATION SMOKE DETECTOR

(71) Applicant: Microchip Technology Incorporated, Chandler, AZ (US)

(72) Inventors: Arthur B. Eck, Gilbert, AZ (US); Jonathan Corbett, Havertown, PA (US); Patrick McFarland, Gilbert, AZ (US)

(73) Assignee: Microchip Technology Incorporated, Chandler, AZ (US)

(21) Appl. No.: 19/056,832

(22) Filed: Feb. 19, 2025

Related U.S. Application Data
(60) Provisional application No. 63/729,801, filed on Dec. 9, 2024.

(51) Int. Cl. H03F 1/02; G01N 27/64; H03F 3/45

(52) U.S. Cl. CPC H03F 1/0222; G01N 27/64; H03F 3/45475; H03F 2200/271

(57) ABSTRACT

A system and method for a drift reset circuit for updating the input offset voltage in an ionization smoke detector are disclosed. The method may include monitoring an ionization chamber of a smoke detector for an alert. The method may also include periodically powering on a drift reset circuit to update an input offset voltage of an operational amplifier. The method may additionally include outputting the input offset voltage to the operational amplifier. The method may further include powering off the drift reset circuit.

### PRIORITY

This application claims priority to U.S. Provisional Patent Application No. 63/729,801 filed Dec. 9, 2024, the contents of which are hereby incorporated in their entirety.

### TECHNICAL FIELD

The present disclosure relates to a drift reset circuit for updating the input offset voltage in an ionization smoke detector, and, in particular to a drift reset circuit that is selectively powered on and off to perform the drift reset.

### BACKGROUND

An ionization smoke detector is a type of smoke detector that uses a small amount of radioactive material to ionize the air within a chamber. This ionization creates a small electric current that is constantly monitored. When smoke particles enter the chamber, they disrupt the ionization process, causing a decrease in the electric current. This change is detected by the smoke detector, triggering an alarm.

Because of the very low currents generated by the ionization, stray leakage current are kept to a minimum to preserve accuracy of the smoke detection. Moisture or dirt on the surface of cable dielectrics and connectors can cause a leakage current which will overwhelm any radiation-induced ion current. Guard rings may be used to reduce leakage through or along the surface of connections between the ionization chamber and other circuits in the smoke detector.

### SUMMARY OF THE INVENTION

Aspects provide systems and methods for a drift reset circuit for updating the input offset voltage in an ionization smoke detector. Examples of the present disclosure may include an apparatus. The apparatus may include a drift reset circuit communicatively coupled to an ionization chamber of a smoke detector and an operational amplifier. The apparatus may also include a control circuit communicatively coupled to the drift reset circuit. The control circuit may be configured to periodically power on the drift reset circuit to update an input offset voltage of the operational amplifier. The control circuit may also be configured to power off the drift reset circuit after updating the input offset voltage.

In combination with any of the above examples, the apparatus may also include a memory trim circuit to store an input offset voltage trim. The control circuit may be configured to calculate the input offset voltage trim. The control circuit may also be configured to store the input offset voltage trim.

In combination with any of the above examples, the control circuit may be configured to periodically activate the drift reset circuit at a predetermined interval.

In combination with any of the above examples, the control circuit may be configured determine whether an offset voltage of the operational amplifier exceeds a predetermined threshold. The control circuit may also be configured to periodically activate the drift reset circuit based on the determination.

In combination with any of the above examples, the drift reset circuit may be an amplifier chopper circuit.

In combination with any of the above examples, the control circuit may be configured to calibrate the input offset voltage. The control circuit may also be configured to wait a predetermined time period for the ionization chamber to stabilize. The control circuit may further be configured to monitor the ionization chamber for an alert.

In combination with any of the above examples, the control circuit may be configured to receive the alert. The control circuit may also be configured to recalibrate the input offset voltage. The control circuit may additionally be configured to determine if the alert is false. The control circuit may further be configured to cancel the alert based on the determination that the alert is false.

Alone or in combination with any of the above examples, examples of the present disclosure may include a method. The method may include monitoring an ionization chamber of a smoke detector for an alert. The method may also include periodically powering on a drift reset circuit to update an input offset voltage of an operational amplifier. The method may additionally include outputting the input offset voltage to the operational amplifier. The method may further include powering off the drift reset circuit.

In combination with any of the above examples, the method may include calculating an input offset voltage trim. The method may also include storing the input offset voltage trim.

In combination with any of the above examples, the method may include determining that a predetermined interval has elapsed. The method may also include periodically activating the drift reset circuit based on the determination.

In combination with any of the above examples, the method may include determining whether an offset voltage of the operational amplifier exceeds a predetermined threshold. The method may also include periodically activating the drift reset circuit based on the determination.

In combination with any of the above examples, the drift reset circuit may be an amplifier chopper circuit.

In combination with any of the above examples, the method may include waiting a predetermined time period for the ionization chamber to stabilize. The method may also include continue monitoring the ionization chamber for an alert.

In combination with any of the above examples, the method may include receiving the alert. The method may also include recalibrating the input offset voltage. The method may additionally include determining if the alert is false. The method may further include cancelling the alert based on the determination that the alert is false.

Alone or in combination with any of the above examples, examples of the present disclosure may include a system. The system may include an ionization chamber of a smoke detector. The system may also include an operational amplifier communicatively coupled to the ionization chamber. The system may additionally include a drift reset circuit communicatively coupled to the ionization chamber and the operational amplifier. The system may further include a control circuit communicatively coupled to the drift reset circuit. The control circuit may be configured to periodically power on the drift reset circuit to update an input offset voltage of the operational amplifier. The control circuit may also be configured to power off the drift reset circuit after updating the input offset voltage.

In combination with any of the above examples, the system may include a memory trim circuit to store an input offset voltage trim. The control circuit may be configured to calculate the input offset voltage trim. The control circuit may also be configured to store the input offset voltage trim.

In combination with any of the above examples, the control circuit may be configured to periodically activate the drift reset circuit at a predetermined interval.

In combination with any of the above examples, the control circuit may be configured to determine whether an offset voltage of the operational amplifier exceeds a predetermined threshold. The control circuit may also be configured to periodically activate the drift reset circuit based on the determination.

In combination with any of the above examples, the control circuit may be configured to calibrate the input offset voltage. The control circuit may also be configured to wait a predetermined time period for the ionization chamber to stabilize. The control circuit may further be configured to monitor the ionization chamber for an alert.

In combination with any of the above examples, the control circuit may be configured to receive the alert. The control circuit may also be configured to recalibrate the input offset voltage. The control circuit may additionally be configured to determine if the alert is false. The control circuit may further be configured to cancel the alert based on the determination that the alert is false.

### BRIEF DESCRIPTION OF THE DRAWINGS

The figures illustrate examples of systems and methods for a drift reset circuit for updating the input offset voltage in an ionization smoke detector.

FIG. 1 illustrates an ionization chamber smoke detector including an analog front end circuit to reset voltage offset drift, according to examples of the present disclosure;

FIG. 2 illustrates an ionization chamber smoke detector including an analog front end circuit to reset voltage offset drift, according to examples of the present disclosure;

FIG. 3 illustrates a control circuit for selectively powering on and off a drift reset circuit of an ionization smoke detector, according to examples of the present disclosure;

FIG. 4 illustrates a method performed for an analog front end that is selectively powered on and off to perform the drift reset in an ionization smoke detector, according to examples of the present disclosure; and

FIG. 5 illustrates a method performed for an analog front end that is selectively powered on and off to perform the drift reset in an ionization smoke detector, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a drift reset circuit for updating the input offset voltage in an ionization smoke detector is provided.

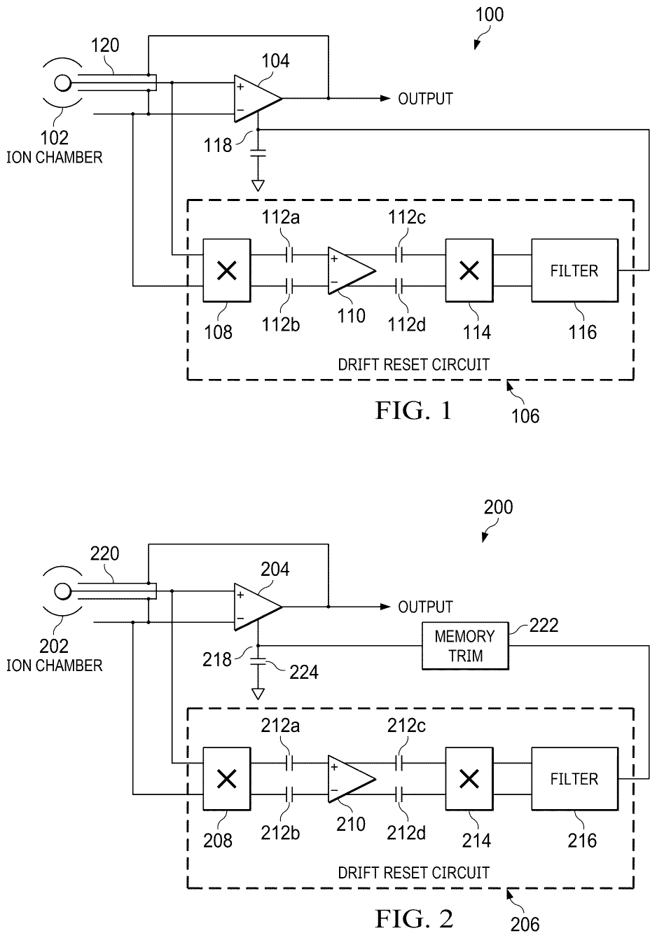

FIG. 1 illustrates an ionization smoke detector including an analog front end circuit to reset voltage offset drift, according to examples of the present disclosure. Ionization chamber 102 used in ionization smoke detector 100 to produce a very small current that is reduced in the presence of smoke particles. Ionization chamber 102 may be include a capacitor with some ionized gas molecules between two capacitor plates. The gas molecules are ionized by the radiation source and, when a voltage is applied between the two capacitor plates, a current will flow through the ionized gas and a resistor connected in series with the capacitor plates. This current produces a voltage across the resistor. By measuring the voltage across the resistor, the permittivity, ε, of the gas may be determined. Smoke in ionization chamber 102 may cause an abrupt change in the permittivity, ε, and, in turn, cause an abrupt change in the current flow and voltage across the resistor. This voltage is measured by operational amplifier 104.

Operational amplifier 104 may be used to convert this current to a voltage that may then be measured to determine the presence of smoke. Elevated temperature and humidity, component aging, dust on a circuit board in ionization smoke detector 100, solder flux, cleaner residue, or any combination thereof may cause increased leakage currents on the inputs of operational amplifier 104 in ionization smoke detector 100. This affects overall performance of the smoke detection function of ionization smoke detector 100. Thus, such increases in leakage currents can pose a variety of problems such as inaccuracy and false alarms which may use additional compensation circuits when designing ionization smoke detector 100 and therefore may increase the cost of ionization smoke detector 100. To compensate for leakage current, ionization smoke detector 100 may use a manufacturing process where pins of sensing integrated circuit of operational amplifier 104 are bent and directly welded in mid-air to ionization chamber 102. However, operational amplifier 104 may have an offset voltage that causes a guard in a Plastic Dual In-Line Packages (PDIP) package to leak. In some examples, drift reset circuit 106 may be used to compensate for the offset voltage, but drift reset circuit 106 may introduce noise, cause load imbalance, introduce injection charge current, and increase energy consumption.

Ionization chamber 102 may be communicatively coupled to operational amplifier 104 using guard lines 120. Guard lines 120 may be used to prevent unwanted electrical currents from interfering with ionization chamber 102. Guard lines 120 may be placed on the circuit board to shield the components and ensure accurate detection of smoke particles. Guard lines 120 may be connected to the same voltage as the electrodes of ionization chamber 102 to maintain the electrical field in ionization chamber 102.

To mitigate the effects of leakage current and offset voltage, ionization smoke detector 100 may include drift reset circuit 106. Drift reset circuit 106 may be used to mitigate the offset voltage of operational amplifier 104 by trimming the offset voltage.

Drift reset circuit 106 may be any suitable amplifier chopper circuit. For example, drift reset circuit 106 may include first chopper switch 108, operational amplifier 110, one or more capacitors 112 for charge storage, second chopper switch 114, and filter 116. In some examples, drift reset circuit 106 may additionally include resistors for setting gain and bias and a clock signal generator to control the switching frequency of first chopper switch 108 or second chopper switch 114. First chopper switch 108 may convert the direct current (DC) signal from ionization chamber 102 to an alternating current (AC) signal. Operational amplifier 110 may amplify the AC signal. The AC signal may then be demodulated by second copper switch 114 to convert the signal back to a DC signal. Filter 116 may filter out noise (e.g., either a low frequencies or high frequencies) from the DC signal output from drift reset circuit 106. The output of drift reset circuit 106 may be communicatively coupled to offset null input pin 118 of operational amplifier 104 to mitigate the offset voltage of operational amplifier 104. Minimizing the offset voltage may mitigate guard leakage to leak to sense and may prevent the practice of bending the sense leads away from the printed circuit board, allowing the use of surface mount packages in ionization smoke detector 100.

Drift reset circuit 106 may be operational when the offset voltage trim of operational amplifier 104 has drifted and is to be reset. Otherwise drift reset circuit 106 may be inoperable. When drift reset circuit 106 is inoperable, drift reset circuit 106 may be powered off and may not consume any power from ionization smoke detector 100. By operating drift reset circuit 106 periodically when the offset voltage is to be reset, the introduction of measurement noise and deviations in injection current caused by drift reset circuit 106 may be reduced. Additionally, the energy requirements of ionization smoke detector 100 may be reduced. Further, because of the reduction in deviation of the injection current, ionization chamber 102 may remain in a stable condition during operation.

FIG. 2 illustrates an ionization smoke detector including an analog front end circuit to reset voltage offset drift, according to examples of the present disclosure. Ionization smoke detector 200 may include ionization chamber 202, operational amplifier 204, drift reset circuit 206, guard lines 220, and memory trim 222. Ionization smoke detector 200, including ionization chamber 202, operational amplifier 204, drift reset circuit 206 (including first chopper switch 108, operational amplifier 210, one or more capacitors 212 for charge storage, second chopper switch 214, and filter 216), and guard lines 220 may be similar to ionization smoke detector 100, chamber 102, operational amplifier 104, and drift reset circuit 106 (including first chopper switch 108, operational amplifier 110, one or more capacitors 112 for charge storage, second chopper switch 114, and filter 116), and guard lines 120, respectively, shown in FIG. 1.

In some examples, the output from drift reset circuit 206 may be stored in memory trim 222. Memory trim 222 may be used in situations where null capacitor 224 may be too leaky or too large to hold the voltage offset drift for a predetermined interval. A designer of ionization smoke detector 200 may consider the design tradeoff between energy use to update null capacitor 224 and the size of null capacitor 224 versus using memory trim 222 to store the output from drift reset circuit 206. Memory trim 222 may be any suitable type of digital or analog memory that can hold or create a voltage value over time such as, but not limited to, a pulse width modulator (PWM), digital-to-analog converter (DAC), a digital potentiometer, a capacitor, or any combination thereof. Memory trim 222 may be communicatively coupled to offset null input pin 218 of operational amplifier 204. For example, memory trim 222 may be used to store the offset voltage trim from drift reset circuit 206 such that the offset voltage trim is supplied to offset null input pin 218 when drift reset circuit 206 is powered off. Memory trim 222 may be used to lock the offset voltage trim of operational amplifier 204 and may increase the time between intervals when drift reset circuit 206 is operational to reset the offset voltage because memory trim 222 may update null capacitor 224 without having to power on drift reset circuit 206.

Similar to drift reset circuit 106, drift reset circuit 206 may be operational when the offset voltage trim of operational amplifier 204 has drifted and is to be reset. Otherwise drift reset circuit 206 may be inoperable. When drift reset circuit 206 is inoperable, drift reset circuit 206 may be powered off and may not consume any power from ionization smoke detector 200. By operating drift reset circuit 206 periodically when the offset voltage is to be reset, the introduction of measurement noise and deviations in injection current caused by drift reset circuit 106 may be reduced. Additionally, the energy requirements of ionization smoke detector 200 may be reduced. Further, because of the reduction in deviation of the injection current, ionization chamber 202 may remain in a stable condition during operation.

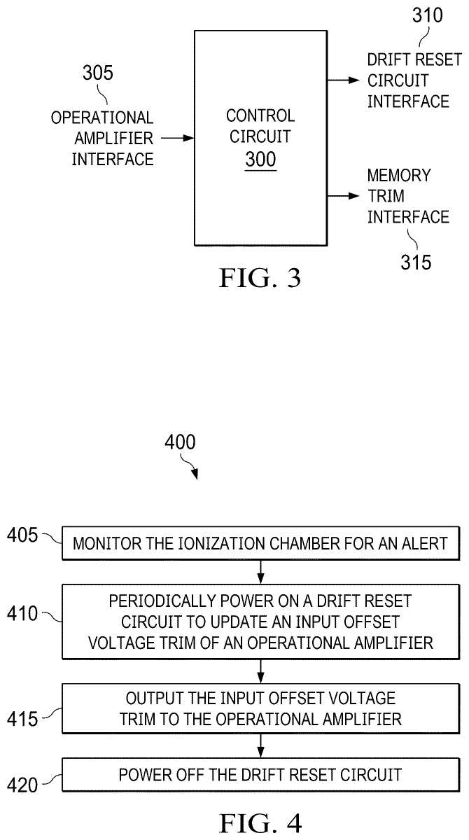

FIG. 3 illustrates a control circuit for selectively powering on and off a drift reset circuit of an ionization chamber smoke detector, according to examples of the present disclosure. Control circuit 300 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 300 may be implemented by instructions for execution by a processor through, for example, a function, application programming interface (API) call, script, program, compiled code, interpreted code, binary, executable, executable file, firmware, object file, container, assembly code, or object. For example, control circuit 300 may be implemented by instructions stored in a non-transitory medium such as a memory that, when loaded and executed by a processor such as a central processing unit (CPU) (or any other suitable process), cause the functionality of control circuit 300 described herein.

Control circuit 300 may be communicatively coupled to operational amplifier interface 305, drift reset circuit interface 310, and memory trim interface 315. Operational amplifier interface 305 may be used by control circuit 300 to monitor the operation of an operational amplifier, such as operational amplifier 104 or operational amplifier 204 shown in FIGS. 1 and 2, respectively. For example, control circuit 300 may monitor the offset voltage of the operational amplifier and determine when the offset voltage trim has drifted beyond a predetermined threshold. The predetermined threshold may be based on, for example, regulations or manufacturing specifications.

Drift reset circuit interface 310 may be used by control circuit 300 to selectively power on and power off a drift reset circuit, such as drift reset circuit 106 or drift reset circuit 206 shown in FIGS. 1 and 2, respectively. For example, when control circuit 300 determines that the offset voltage trim has drifted beyond a predetermined threshold, control circuit may power on the drift reset circuit, via drift reset circuit interface 310, such that the drift reset circuit resets the offset voltage trim.

Memory trim interface 315 may be used by control circuit 300 to update a memory trim, such as memory trim 222 shown in FIG. 2. For example, when control circuit 300 determines that the offset voltage trim has drifted beyond a predetermined threshold, control circuit may power on the drift reset circuit to update the offset voltage trim and may cause the offset voltage trim to be stored in the memory trim.

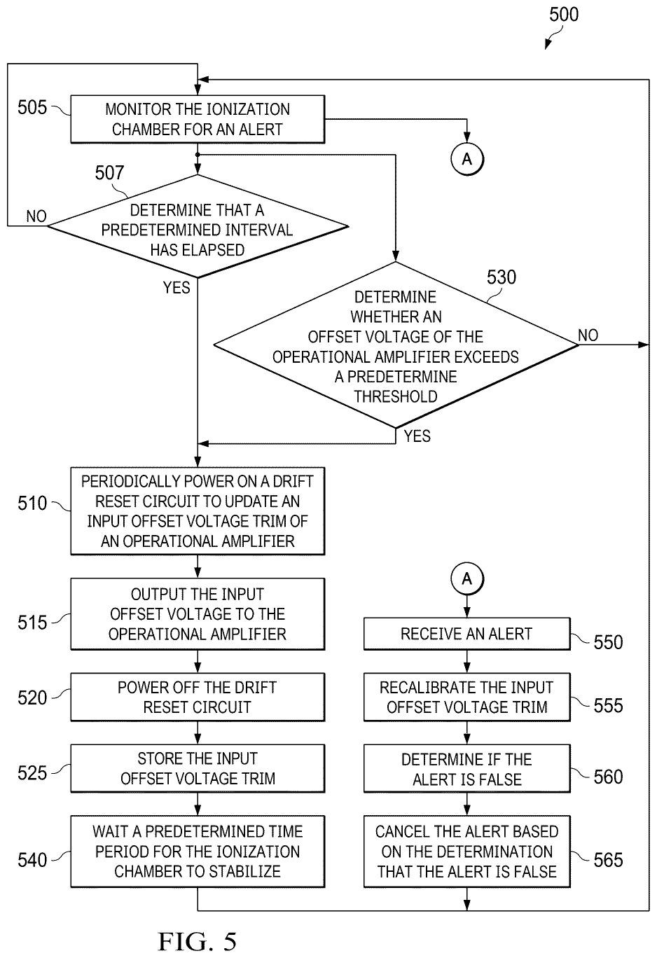

The functions of control circuit 300 are described in more detail with respect to FIGS. 4 and 5.

FIG. 4 illustrates a method performed for an analog front end that is selectively powered on and off to perform the drift reset in an ionization smoke detector, according to examples of the present disclosure. Method 400 may be implemented using an ionization smoke detector, in combination with a control circuit, such as control circuit 300 shown in FIG. 3, using a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, core independent peripheral (CIP), discrete gate or transistor logic, discrete hardware components, other programmable device, or any combination thereof designed to perform the functions disclosed herein, in combination with a processor, or any other system operable to implement method 400. Although examples have been described above, other variations and examples may be made from this disclosure without departing from the spirit and scope of these disclosed examples.

Method 400 may begin at block 405 where an ionization chamber of a smoke detector may be monitored for an alert. During monitoring, the profile of the ionization chamber may be monitored for variations to determine if the variation is due to smoke generated by a fire or a false alarm. During use of the ionization smoke detector, method 400 may operate at block 405 for most of the lifespan of the ionization smoke detector. The ionization chamber may be communicatively coupled to an operational amplifier, such as operational amplifier 104 or 204 shown in FIGS. 1 and 2, respectively. The operational amplifier may have an offset voltage. A drift reset circuit may be used to provide an offset voltage trim to negate the offset voltage of the operational amplifier.

At block 410, the drift reset circuit may be periodically powered on to update an input offset voltage trim of an operational amplifier. The drift reset circuit, such as drift reset circuit 106 or 206 shown in FIGS. 1 and 2, respectively, may be used to compensate for the offset voltage of the operational amplifier, but may introduce noise, cause load imbalance, introduce injection charge current, and increase energy consumption. Therefore, the drift reset circuit may be operational when the offset voltage trim of the operational amplifier has drifted or after a predetermined interval has elapsed and the offset voltage trim is to be reset. Otherwise the drift reset circuit may be inoperable, powered off, and not consume any power. The drift reset circuit may update the input offset voltage trim in a short period of time (e.g., on the order of microseconds) such that the operation of the drift reset circuit does not introduce factors that may impact the ionization chamber. Additionally, the drift reset circuit may operation outside of the measurement cycle to mitigate any impacts on the ionization chamber.

At block 415, the input offset voltage trim may be output to the operational amplifier. The input offset voltage trim may be output by the drift reset circuit and communicatively coupled to an offset null input pin of the operational amplifier (e.g., offset null input pin 118 or 218 shown in FIGS. 1 and 2, respectively).

At block 420, the drift reset circuit may be powered off. By powering off the drift reset circuit, the introduction of measurement noise and deviations in injection current caused by the drift reset circuit may be reduced.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

FIG. 5 illustrates a method performed for an analog front end that is selectively powered on and off to perform the drift reset in an ionization smoke detector, according to examples of the present disclosure. Method 500 may be implemented using an ionization smoke detector, in combination with a control circuit, such as control circuit 300 shown in FIG. 3, using a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, core independent peripheral (CIP), discrete gate or transistor logic, discrete hardware components, other programmable device, or any combination thereof designed to perform the functions disclosed herein, in combination with a processor, or any other system operable to implement method 500. Although examples have been described above, other variations and examples may be made from this disclosure without departing from the spirit and scope of these disclosed examples.

Method 500 may begin at block 505 where an ionization chamber of a smoke detector may be monitored for an alert. During monitoring, the profile of the ionization chamber may be monitored for variations to determine if the variation is due to smoke generated by a fire or a false alarm. If a variation is detected, method 500 may proceed to block 550. During use of the ionization smoke detector, method 500 may operate at block 505 for most of the lifespan of the ionization smoke detector. The ionization chamber may be communicatively coupled to an operational amplifier, such as operational amplifier 104 or 204 shown in FIGS. 1 and 2, respectively. The operational amplifier may have an offset voltage. A drift reset circuit may be used to provide an offset voltage trim to negate the offset voltage of the operational amplifier.

At block 507, whether a predetermined interval has elapsed may be determined. The predetermined interval may be set by, for example, regional requirements, manufacturing aging data, and the manufacturer's marketing goals. In some examples, the interval may not be exceeded during the lifespan of the ionization smoke detector when the calibration is performed at one time and not again unless an alert is triggered. If the predetermined interval has elapsed, method 500 may proceed to block 510 to update an input offset voltage trim of the operational amplifier. If the predetermined interval has not elapsed, method 500 may return to block 505 and continue monitoring the ionization chamber.

At block 510, a drift reset circuit may be periodically powered on to update the input offset voltage trim of the operational amplifier. The drift reset circuit, such as drift reset circuit 106 or 206 shown in FIGS. 1 and 2, respectively, may be used to compensate for the offset voltage of the operational amplifier, but may introduce noise, cause load imbalance, introduce injection charge current, and increase energy consumption. Therefore, the drift reset circuit may be operational when the offset voltage trim of the operational amplifier has drifted and is to be reset. Otherwise the drift reset circuit may be inoperable, powered off, and not consume any power.

At block 515, the input offset voltage trim may be output to the operational amplifier. The input offset voltage trim may be output by the drift reset circuit and communicatively coupled to an offset null input pin of the operational amplifier (e.g., offset null input pin 118 or 218 shown in FIGS. 1 and 2, respectively).

At block 520, the drift reset circuit may be powered off. By powering off the drift reset circuit, the introduction of measurement noise and deviations in injection current caused by the drift reset circuit may be reduced. Blocks 510, 515, and 520 are considered calibration of the input offset voltage trim. The calibration may account for any debris buildup on the printed circuit board, circuitry aging, influences of temperature on circuitry, any other suitable consideration, or any combination thereof.

At block 525, the input offset voltage trim may be stored. For example, the input offset voltage trim may be stored in a memory trim, such as memory trim 222 in FIG. 2. The memory trim may be any suitable type of memory such as non-volatile memory or analog memory and may be communicatively coupled to the offset null input pin and null capacitor of the operational amplifier.

At block 530, whether an offset voltage of the operational amplifier exceeds a predetermined threshold may be determined. If the offset voltage has exceeded the predetermined threshold, method 500 may return to block 510 to update the input offset voltage trim. If the predetermined threshold has not been exceeded, method 500 may return to block 505 and continue monitoring the ionization chamber. The predetermined threshold may be based on, for example, regulations or manufacturing specifications.

After calibration of the input offset voltage trim (at blocks 510, 515, and 520), at block 540, the system may wait for the ionization chamber to stabilize for a predetermined time period. The stabilization time of the ionization chamber may be a short period of time, for example less than one second. Method 500 may return to block 505 after the ionization chamber is stabilized to monitor the ionization chamber for an alert.

At block 550, an alert may be received indicating that a variation has been detected in the ionization chamber. At block 555, the input offset voltage trim may be recalibrated (by repeating blocks 510, 515, and 520). The recalibration may account for any debris buildup on the printed circuit board, circuitry aging, influences of temperature on circuitry, any other suitable consideration, or any combination thereof, to determine, at block 560, whether the alert is false (e.g., that the alert was caused by any of these considerations and not by the presence of smoke in the ionization chamber).

At block 565, if the alert is determined to be false, the alert may be cancelled. Method 500 may return to block 505 to continue monitoring the ionization chamber. If a change is detected that is not a false alarm, method 500 may trigger an alarm.

The implementation of method 500 may take the lifespan of the ionization smoke detector into consideration. For example, the ionization smoke detector may be expected to have a lifespan of 10 years using a battery that is sealed into the ionization smoke detector. Method 500 may be implemented to conserve energy to achieve the expected lifespan. Method 500 may be implemented to reduce energy consumption and cost of the circuitry implementing method 500.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

Although examples have been described above, other variations and examples may be made from this disclosure without departing from the spirit and scope of these disclosed examples.

1. An apparatus, comprising:
a drift reset circuit communicatively coupled to an ionization chamber of a smoke detector and an operational amplifier; and
a control circuit communicatively coupled to the drift reset circuit, the control circuit to:
periodically power on the drift reset circuit to update an input offset voltage of the operational amplifier; and
power off the drift reset circuit after updating the input offset voltage.

2. The apparatus of claim 1, comprising a memory trim circuit to store an input offset voltage trim;
wherein the control circuit is to:
calculate the input offset voltage trim; and
store the input offset voltage trim.

3. The apparatus of claim 1, wherein the control circuit is to periodically activate the drift reset circuit at a predetermined interval.

4. The apparatus of claim 1, wherein the control circuit is to:
determine whether an offset voltage of the operational amplifier exceeds a predetermined threshold; and
periodically activate the drift reset circuit based on the determination.

5. The apparatus of claim 1, wherein the drift reset circuit is an amplifier chopper circuit.

6. The apparatus of claim 1, wherein the control circuit is to:
calibrate the input offset voltage;
wait a predetermined time period for the ionization chamber to stabilize; and
monitor the ionization chamber for an alert.

7. The apparatus of claim 6, wherein the control circuit is to:
receive the alert;
recalibrate the input offset voltage;
determine if the alert is false; and
cancel the alert based on the determination that the alert is false.

8. A method, comprising:
monitoring an ionization chamber of a smoke detector for an alert;
periodically powering on a drift reset circuit to update an input offset voltage of an operational amplifier;
outputting the input offset voltage to the operational amplifier; and
powering off the drift reset circuit.

9. The method of claim 8, comprising:
calculating an input offset voltage trim; and
storing the input offset voltage trim.

10. The method of claim 8, comprising:
determining that a predetermined interval has elapsed; and
periodically activating the drift reset circuit based on the determination.

11. The method of claim 8, comprising:
determining whether an offset voltage of the operational amplifier exceeds a predetermined threshold; and
periodically activating the drift reset circuit based on the determination.

12. The method of claim 8, wherein the drift reset circuit is an amplifier chopper circuit.

13. The method of claim 8, comprising:
waiting a predetermined time period for the ionization chamber to stabilize; and
continue monitoring the ionization chamber for an alert.

14. The method of claim 13, comprising:
receiving the alert;
recalibrating the input offset voltage;
determining if the alert is false; and
cancelling the alert based on the determination that the alert is false.

15. A system, comprising:
an ionization chamber of a smoke detector;
an operational amplifier communicatively coupled to the ionization chamber;
a drift reset circuit communicatively coupled to the ionization chamber and the operational amplifier; and
a control circuit communicatively coupled to the drift reset circuit, the control circuit to:
periodically power on the drift reset circuit to update an input offset voltage of the operational amplifier; and
power off the drift reset circuit after updating the input offset voltage.

16. The system of claim 15, comprising a memory trim circuit to store an input offset voltage trim;
wherein the control circuit is to:
calculate the input offset voltage trim; and
store the input offset voltage trim.

17. The system of claim 15, wherein the control circuit is to periodically activate the drift reset circuit at a predetermined interval.

18. The system of claim 15, wherein the control circuit is to:
determine whether an offset voltage of the operational amplifier exceeds a predetermined threshold; and
periodically activate the drift reset circuit based on the determination.

19. The system of claim 15, wherein the control circuit is to:
calibrate the input offset voltage;
wait a predetermined time period for the ionization chamber to stabilize; and
monitor the ionization chamber for an alert.

20. The system of claim 19, wherein the control circuit is to:
receive the alert;
recalibrate the input offset voltage;
determine if the alert is false; and
cancel the alert based on the determination that the alert is false.
